(19) United States
(12) Patent Application Publication
(10) Pub. No.: US 2020/0168858 A1
(43) Pub. Date: May 28, 2020

(54) ELECTRIC VEHICLE BATTERY CELL WITH DUAL POLARITY LID

(71) Applicant: SF Motors, Inc., Santa Clara, CA (US)

(72) Inventors: Scott Quinlan Freeman Monismith, Santa Clara, CA (US); Jeremy Elsberry, Santa Clara, CA (US); Derek Wong, Santa Clara, CA (US); Ying Liu, Santa Clara, CA (US); Yifan Tang, Santa Clara, CA (US); Ray Kairawicz, Santa Clara, CA (US)

(21) Appl. No.: 16/203,313

(22) Filed: Nov. 28, 2018

(51) Int. Cl. H01M 2/04; H01M 2/30; H01M 2/10; H05K 5/06; H01M 2/02; H01M 2/08

(52) U.S. Cl. CPC H01M 2/043; B60L 11/1879; H01M 2/305; H01M 2/1072; H01M 2220/20; H01M 2/0237; H01M 2/0482; H01M 2/08; H01M 2/0486; H05K 5/061

(57) ABSTRACT

Provided herein is a dual polarity lid for a battery cell of a battery pack to power an electric vehicle. The dual polarity lid can include a first polarity region and an inner gasket disposed within an inner edge surface of the first polarity region. The lid can include a fuse layer disposed within an inner isolation surface of the inner gasket. The lid can include an isolation layer coupled with a second surface of the fuse layer. The lid can include a second polarity region coupled with a second surface of the isolation layer such that the isolation layer is disposed between the fuse layer and the second polarity region. The lid can include an outer gasket coupled with the outer edge surface of the first polarity region, and the outer gasket coupled with the first end of the housing to seal the battery cell.

### BACKGROUND

Batteries can include electrochemical materials to supply electrical power to electrical components connected thereto. Such batteries can provide electrical energy to electrical systems.

### SUMMARY

At least one aspect is directed to a battery cell of a battery pack to power an electric vehicle. The battery cell can include a housing having a first end and a second end. The housing can define an inner region. An electrolyte can be disposed in the inner region defined by the housing. A lid can couple with a first end of the housing. The lid can include a first polarity region having an inner edge surface and an outer edge surface. The lid can include an inner gasket disposed within the inner edge surface of the first polarity region. The inner gasket can have an inner isolation surface. The lid can include a fuse layer disposed within the inner isolation surface of the inner gasket. The fuse layer can have a first surface and a second surface. The lid can include an isolation layer having a first surface and a second surface. The first surface of the isolation layer can couple with the second surface of the fuse layer. The lid can include a second polarity region having a first surface and a second surface. The first surface of the second polarity region can couple with the second surface of the isolation layer such that the isolation layer is disposed between the second surface of the fuse layer and the first surface of the second polarity region. The lid can include an outer gasket coupled with the outer edge surface of the first polarity region, and the outer gasket coupled with the first end of the housing to seal the battery cell.

At least one aspect is directed to a method of providing a battery cell of a battery pack to power an electric vehicle. The method can include providing a battery pack having a battery cell. The battery cell can include a housing that include a first end and a second end and defines an inner region. The method can include disposing an electrolyte within the inner region. The method can include providing a first polarity region having an inner edge surface and an outer edge surface. The method can include disposing an inner gasket within the inner edge surface of the first polarity region. The inner gasket can have an inner isolation surface. The method can include positioning a fuse layer within the inner isolation surface of the inner gasket. The fuse layer can have a first surface and a second surface. The method can include coupling a first surface of an isolation layer with the second surface of the fuse layer. The isolation layer can have the first surface and a second surface. The method can include providing a second polarity region having a first surface and a second surface. The first surface of the second polarity region can couple with the second surface of the isolation layer such that the isolation layer is disposed between the second surface of the fuse layer and the first surface of the second polarity region. The method can include crimping an outer gasket with the outer edge surface of the first polarity region to form a lid for the battery cell. The method can include coupling the outer gasket with the first end of the housing to seal the battery cell.

At least one aspect is directed to a method. The method can provide a battery cell of a battery pack of an electric vehicle. The battery cell can include a housing having a first end and a second end. The housing can define an inner region. An electrolyte can be disposed in the inner region defined by the housing. A lid can couple with a first end of the housing. The lid can include a first polarity region having an inner edge surface and an outer edge surface. The lid can include an inner gasket disposed within the inner edge surface of the first polarity region. The inner gasket can have an inner isolation surface. The lid can include a fuse layer disposed within the inner isolation surface of the inner gasket. The fuse layer can have a first surface and a second surface. The lid can include an isolation layer having a first surface and a second surface. The first surface of the isolation layer can couple with the second surface of the fuse layer. The lid can include a second polarity region having a first surface and a second surface. The first surface of the second polarity region can couple with the second surface of the isolation layer such that the isolation layer is disposed between the second surface of the fuse layer and the first surface of the second polarity region. The lid can include an outer gasket coupled with the outer edge surface of the first polarity region, and the outer gasket coupled with the first end of the housing to seal the battery cell.

At least one aspect is directed to an electric vehicle. The electric vehicle can include a battery cell of a battery pack of an electric vehicle. The battery cell can include a housing having a first end and a second end. The housing can define an inner region. An electrolyte can be disposed in the inner region defined by the housing. A lid can couple with a first end of the housing. The lid can include a first polarity region having an inner edge surface and an outer edge surface. The lid can include an inner gasket disposed within the inner edge surface of the first polarity region. The inner gasket can have an inner isolation surface. The lid can include a fuse layer disposed within the inner isolation surface of the inner gasket. The fuse layer can have a first surface and a second surface. The lid can include an isolation layer having a first surface and a second surface. The first surface of the isolation layer can couple with the second surface of the fuse layer. The lid can include a second polarity region having a first surface and a second surface. The first surface of the second polarity region can couple with the second surface of the isolation layer such that the isolation layer is disposed between the second surface of the fuse layer and the first surface of the second polarity region. The lid can include an outer gasket coupled with the outer edge surface of the first polarity region, and the outer gasket coupled with the first end of the housing to seal the battery cell.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE DRAWINGS

The accompanying drawings are not intended to be drawn to scale. Like reference numbers and designations in the various drawings indicate like elements. For purposes of clarity, not every component can be labeled in every drawing. In the drawings:

FIG. 1 is a block diagram depicting a cross-sectional view of an example battery cell for a battery pack in an electric vehicle, according to an illustrative implementation;

FIG. 2 is a diagram depicting an exploded view of the different layers of a lid of a battery cell for a battery pack in an electric vehicle, according to an illustrative implementation;

FIG. 3 is a top view of a lid for a battery cell for a battery pack in an electric vehicle, according to an illustrative implementation;

FIG. 4 is a bottom view of a lid for a battery cell for a battery pack in an electric vehicle, according to an illustrative implementation;

FIG. 5 is a block diagram depicting a cross-sectional view of an example battery pack for holding battery cells in an electric vehicle;

FIG. 6 is a block diagram depicting a cross-sectional view of an example electric vehicle installed with a battery pack;

FIG. 7 is a flow diagram depicting an example method of providing a lid for a battery cell of a battery pack to power an electric vehicle; and

FIG. 8 is a flow diagram depicting an example method of providing battery cells for battery packs for electric vehicles.

### DETAILED DESCRIPTION

Following below are more detailed descriptions of various concepts related to, and implementations of battery cells for battery packs in electric vehicles. The various concepts introduced above and discussed in greater detail below can be implemented in any of numerous ways.

Systems and methods described herein relates to a dual polarity lid for a battery cell of a battery pack of an electric vehicle. The lid can be formed as an annular lid having multiple layers of aluminum material and provide multiple terminals for coupling with a busbar of a battery pack of an electric vehicle. For example, at least two of the layers can provide terminals for the battery cell. A first polarity layer can correspond to a first polarity terminal for the battery cell and a second polarity layer can correspond to a second polarity terminal for the battery cell. The different polarity terminals can be isolated by at least one isolation layer. The different polarity layers provided at the same end of the battery cell can provide increased corrosion resistance and a stronger (lower) impedance weld with increased yield for both a positive and negative terminal of the battery cell.

The dual polarity lid can include at least one positive surface and at least one negative surface for coupling with positive and native busbars of a battery pack of an electric vehicle. The lid can include at least one layer to respond to an external short or short circuit condition. For example, the lid can include a fuse layer that responds to a short circuit condition. The fuse layer can include an inner region (e.g., punch out region) that breaks an electrical connection between different terminals of the battery cell in response to a short circuit condition. The lid can include a vent plate that responds to a short circuit condition. The vent plate can include an inner region (e.g., hinge region) that breaks in response to a pressure within the battery cell being greater than a pressure threshold. Thus, the battery cell as described herein can provide one or more forms of protection against an external short or short circuit condition.

The lid can include at least one fuse component or current interrupter component to break electrical connection between the different terminals of the battery cell in response to an external short or mechanical deformation of the battery cell. The lid can include at least one vent plate component to operate as a vent during a thermal event or over pressurization of the battery cell. Thus, the lid of the battery cells described herein can provide multiple layers for protection against electrical, thermal or deformation events occurring within or to the respective battery cells.

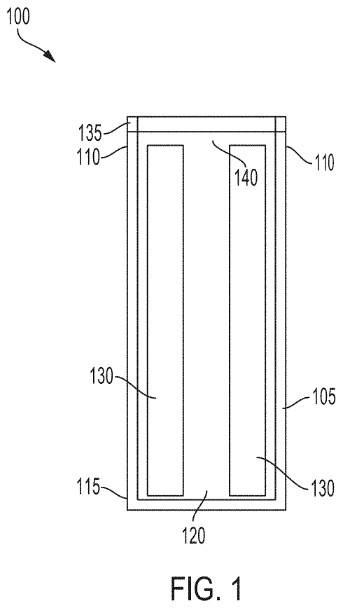

FIG. 1, among others, depicts a cross-sectional view of a battery cell 100 for a battery pack in an electric vehicle. The battery cell 100 can provide energy or store energy for an electric vehicle. For example, the battery cell 100 can be included in a battery pack used to power an electric vehicle. The battery cell 100 can include at least one housing 105. The housing 105 can have a first end 110 and a second end 115. The battery cell 100 can be a lithium-air battery cell, a lithium ion battery cell, a nickel-zinc battery cell, a zinc-bromine battery cell, a zinc-cerium battery cell, a sodium-sulfur battery cell, a molten salt battery cell, a nickel-cadmium battery cell, or a nickel-metal hydride battery cell, among others. The housing 105 can be included or contained in a battery pack (e.g., a battery array or battery module) installed a chassis of an electric vehicle. The housing 105 can have the shape of a cylindrical casing or cylindrical cell with a circular, ovular, or elliptical base, as depicted in the example of the battery cell of FIG. 1. A height of the housing 105 can be greater than a width of the housing 105. For example, the housing 105 can have a length (or height) in a range from 65 mm to 75 mm and a width (or diameter for circular examples) in a range from 15 mm to 27 mm. In some examples the width or diameter of the housing 105 can be greater than the length (e.g., height) of the housing 105. The housing 105 can be formed from a prismatic casing with a polygonal base, such as a triangle, square, a rectangular, a pentagon, or a hexagon, for example. A height of such a prismatic cell housing 105 can be less than a length or a width of the base of the housing 105. The battery cell 100 can be a cylindrical cell 21 mm in diameter and 70 mm in height. Other shapes and sizes are possible, such as a rectangular cells or rectangular cells with rounded edges, of cells between 15 mm to 27 mm in diameter or width, and 65 mm to 75 mm in length or height.

The housing 105 of the battery cell 100 can include at least one electrically or thermally conductive material, or combinations thereof. The electrically conductive material can also be a thermally conductive material. The electrically conductive material for the housing 105 of the battery cell 100 can include a metallic material, such as aluminum, an aluminum alloy with copper, silicon, tin, magnesium, manganese or zinc (e.g., of the aluminum 4000 or 5000 series), iron, an iron-carbon alloy (e.g., steel), silver, nickel, copper, and a copper alloy, among others. The electrically conductive material and thermally conductive material for the housing 105 of the battery cell 100 can include a conductive polymer. To evacuate heat from inside the battery cell 100, the housing 105 can be thermally coupled to a thermoelectric heat pump (e.g., a cooling plate) via an electrically insulating layer. The housing 105 can include an electrically insulating material. The electrically insulating material can be a thermally conductive material. The electrically insulating and thermally conductive material for the housing 105 of the battery cell 100 can include a ceramic material (e.g., silicon nitride, silicon carbide, titanium carbide, zirconium dioxide, beryllium oxide, and among others) and a thermoplastic material (e.g., polyethylene, polypropylene, polystyrene, or polyvinyl chloride), among others. To evacuate heat from inside the battery cell 100, the housing 105 can be thermally coupled to a thermoelectric heat pump (e.g., a cooling plate). The housing 105 can be directly thermally coupled to the thermoelectric heat pump without an addition of an intermediary electrically insulating layer.

The housing 105 of the battery cell 100 can include the first end 110 (e.g., top portion) and the second end 115 (e.g., bottom portion). The housing 105 can define an inner region 120 between the first end 110 and the second end 115. For example, the inner region 120 can include an interior of the housing 105 or an inner area formed by the housing 105. The first end 110, inner region 120, and the second end 115 can be defined along one axis of the housing 105. For example, the inner region 120 can have a width (or diameter for circular examples) of 2 mm to 6 mm and a length (or height) of 50 mm to 70 mm. The width or length of the inner region 120 can vary within or outside these ranges. The first end 110, inner region 120, and second end 115 can be defined along a vertical (or longitudinal) axis of cylindrical casing forming the housing 105. The first end 110 at one end of the housing 105 (e.g., a top portion as depicted in FIG. 1). The second end 115 can be at an opposite end of the housing 105 (e.g., a bottom portion as depicted in FIG. 1). The end of the second end 115 can encapsulate or cover the corresponding end of the housing 105.

The diameter (or width) of the first end 110 can be in a range from 15 mm to 27 mm. The diameter (or width) of the second end 115 can be in a range from 15 mm to 27 mm. The diameter (or width) can correspond to a shortest dimension along an inner surface of the housing 105 within the first end 110 or second end 115. The width can correspond to a width of a rectangular or polygonal lateral area of the first end 110 or second end 115. The diameter (or width) can correspond to a diameter of a circular or elliptical lateral area of the first end 110 or second 115. The width of the first end 110 (not including the indentation) can be less than the width of the second end 115 of the housing 105. The lateral area of the first end 110 (not including the indentation) can be less than the lateral area of the second end 115 of the housing 105.

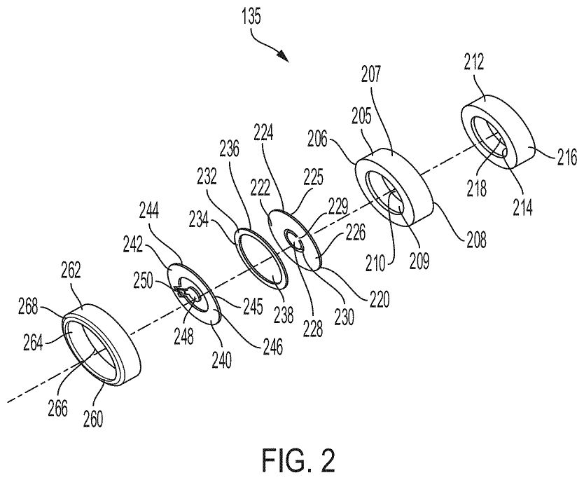

At least one electrolyte 130 can be disposed in the inner region 120 of the housing 105. The battery cell 100 can include multiple electrolytes 130 disposed in the inner region 120 of the housing. The electrolyte 130 can include a first polarity electronic charge region or terminus and a second polarity electronic charge region or terminus. For example, the electrolyte 130 can include a positive electronic charge region or terminus and a negative electronic charge region or terminus. A first polarity tab (e.g., negative tab) can couple a first polarity region of the electrolyte with a first polarity layer or first polarity region (e.g., first polarity region 205 of FIG. 2) of a lid 135 to form a first polarity surface area (e.g., negative surface area) on the lid 135 for first polarity wire bonding. At least one second polarity tab (e.g., positive tab) can couple a second polarity region of the electrolyte 130 (e.g., positive region of electrolyte 130) with a second polarity layer or second polarity region (e.g., second polarity region 220 of FIG. 2) of the lid 135. The electrolyte 130 can include any electrically conductive solution, dissociating into ions (e.g., cations and anions). For a lithium-ion battery cell, for example, the electrolyte 130 can include a liquid electrolyte, such as lithium bisoxalatoborate (LiBC4O8 or LiBOB salt), lithium perchlorate (LiClO4), lithium hexaflourophosphate (LiPF6), and lithium trifluoromethanesulfonate (LiCF3SO3). The electrolyte 130 can include a polymer electrolyte, such as polyethylene oxide (PEO), polyacrylonitrile (PAN), poly (methyl methacrylate) (PMMA) (e.g., acrylic glass), or polyvinylidene fluoride (PVdF). The electrolyte 130 can include a solid-state electrolyte, such as lithium sulfide (Li2S), magnesium, sodium, and ceramic materials (e.g., beta-alumna). A single electrolyte 130 can be disposed within inner region 120 of the housing 105 or multiple electrolytes 130 (e.g., two electrolytes, more than two electrolytes) can be disposed within inner region 120 of the housing 105. For example, two electrolytes 130 can be disposed within inner region 120 of the housing 105. The number of electrolytes 130 can vary and can be selected based at least in part on a particular application of the battery cell 100.

At least one lid 135 can be disposed proximate to the first end 110 of the housing 105. The lid 135 can be disposed onto the first lateral end 110 of the housing 105. The lid 135 can be crimped onto, clipped onto, or welded with the first end 110 to couple the lid 135 with the first end 110 of the housing 105. The coupling (e.g., crimped coupling, welded coupling) between the lid 135 and the first end 110 of the housing 105 can form a hermetic seal, a fluid resistant seal, or a hermetic seal and a fluid resistant seal between the lid 135 and the housing 105, for example, so that the fluid or material within the inner region 120 does not leak from its location within the housing 105. The lid 135 can have a diameter in a range from 12 mm to 30 mm. The diameter of the lid 135 can vary within or outside this range. The lid 135 can have a width (e.g. vertical width, height) in a range from 0.5 mm to 10 mm. The height of the lid 135 can vary within or outside this range.

An insulation material 140 can be disposed between the electrolyte 130 and one or more portions of the lid 135 or the housing 105. The insulation material 140 can separate or electrically isolate the electrolyte 130 from one or more portions of the lid 135 or the housing 105. An insulation material 140 may be disposed between an inner surface of the housing 105 and the electrolyte 130 disposed within the inner region 120 of the housing 105 to electrically insulate the housing 105 from the electrolyte 130. The insulation material 140 may include dielectric material. For example, the insulation material 140 can include polymer material, insulation material, plastic material, epoxy material, FR-4 material, polypropylene materials, or formex materials, among others.

FIG. 2, among others, depicts an exploded view of the different layers of a lid 135 for a battery cell 100. The lid 135 includes a plurality of layers to provide a dual polarity lid having both at least one positive surface and at least one negative surface for coupling with positive and negative busbars of a battery pack of an electric vehicle. The lid 135 includes a fuse component or current interrupter component to break electrical connection between the different terminals of the battery cell in response to an external short or mechanical deformation of the battery cell 100. For example, the lid 135 includes a first polarity region 205. The first polarity region 205 can include an outer edge surface 207 (e.g., outer side surface), an inner edge surface 209 (e.g., inner side surface), and an orifice 210. The first polarity region 205 can include a first surface 206 (e.g., top surface) and a second surface 208 (e.g., bottom surface). The orifice 210 can be formed through the first polarity region 205 to provide an opening or hole through the first polarity region 205. For example, the inner edge surface 209 can form a wall or border of the orifice 210. The orifice 210 can be formed having a shape corresponding to the shape of the first polarity region 205. The orifice 210 can be formed having a circular shape, square shape, an elliptical shape, a triangular shape, a rectangular shape, a hexagonal shape, or an octagonal shape. The outer edge surface 207 can form an outer edge or side surface of the first polarity region 205.

The first polarity region 205 can be formed having a shape corresponding to the shape of the housing 105 of the battery cell 100 and thus, the battery cell 100. The first polarity region 205 can be formed having a circular shape, square shape, an elliptical shape, a triangular shape, a rectangular shape, a hexagonal shape, or an octagonal shape. The first polarity region 205 can include electrically conductive material, such as a metallic material, aluminum, or an aluminum alloy with copper. For example, the first polarity region 205 can include an aluminum cup. A width of the first polarity region 205 can range from 0.5 mm to 10 mm. The width of the first polarity region 205 can vary within or outside this range. A thickness of the first polarity region 205 (e.g., a distance from the outer edge surface 207 to the inner edge surface 209) can range from 6 mm to 15 mm. The thickness of the first polarity region 205 can vary within or outside this range. A diameter (e.g., including orifice 210) of the first polarity region 205 can range from 12 mm to 25 mm. The diameter of the first polarity region 205 can vary within or outside this range. A diameter of the orifice 210 can range from 1 mm to 15 mm. The diameter of the orifice 210 can vary within or outside this range.

The lid 135 can include an inner gasket 212. For example, the inner gasket 212 can be disposed within or coupled with the inner edge surface 209 of the first polarity region 205. The inner gasket 212 can include an inner isolation surface 214 (e.g., inner side surface), an outer isolation surface 216 (e.g., outer side surface), and an orifice 218. The outer isolation surface 216 can form an outer edge or side surface of the inner gasket 212. The outer isolation surface 216 can be coupled with or in contact with the inner edge surface 209 of the first polarity region 205 when the inner gasket 212 is disposed within the first polarity region 205. An adhesive layer or adhesive material can couple the inner gasket 212 with the first polarity region 205. For example, an adhesive layer or adhesive material can couple the outer isolation surface 216 with the inner edge surface 209 of the first polarity region 205 when the inner gasket 212 is disposed within the first polarity region 205. The orifice 218 can include an opening or hole formed through the inner gasket 212. For example, the inner isolation surface 214 can form a wall or border of the orifice 218. The orifice 218 can be formed having a shape corresponding to the shape of the inner gasket 212. For example, the orifice 218 can be formed having a circular shape, square shape, an elliptical shape, a triangular shape, a rectangular shape, a hexagonal shape, or an octagonal shape.

The inner gasket 212 can be formed having a shape corresponding to the shape of the housing 105 of the battery cell 100. For example, the inner gasket 212 can be formed having a circular shape, square shape, an elliptical shape, a triangular shape, a rectangular shape, a hexagonal shape, or an octagonal shape. The inner gasket 212 can include non-conductive material, such as a polymer material, insulation material, plastic material, glass material, ceramic material or epoxy material. For example, the inner gasket 212 can include an electrically insulating polymer. A width of the inner gasket 212 can range from 0.5 mm to 15 mm. The width of the inner gasket 212 can vary within or outside this range. A thickness of the inner gasket 212 (e.g., a distance from the outer isolation surface 216 to the inner isolation surface 214) can range from 4 mm to 15 mm. The thickness of the inner gasket 212 can vary within or outside this range. A diameter of the inner gasket 212 can range from 12 mm to 25 mm. The diameter of the inner gasket 212 can vary within or outside this range. A diameter of the orifice 218 can range from 1 mm to 15 mm. The diameter of the orifice 218 can vary within or outside this range.

The lid 135 can include a second polarity region 220. The second polarity region 220 can have a different polarity than the first polarity region 205. For example, the first polarity region 205 can correspond to a negative polarity region and the second polarity region 220 can correspond to a positive polarity region. The first polarity region 205 can correspond to a positive polarity region and the second polarity region 220 can correspond to a negative polarity region. The second polarity region 220 can be disposed within or couple with the inner gasket 212. For example, the second polarity 220 can include a first surface 222 (e.g., top surface), a second surface 224 (e.g., bottom surface), and an outer edge 225. The second polarity region 220 can be disposed within or couple with the inner gasket 212 such that the outer edge 225 of the second polarity region 220 couples with or is in contact with the inner isolation surface 214 of the second polarity region 220. The second surface 224 of the second polarity region 220 can couple with or be in contact with the inner isolation surface 214 of the inner gasket 212. An adhesive layer or adhesive material can couple the second polarity region 220 with the inner gasket 212. For example, an adhesive layer or adhesive material can couple the second surface 224 with the inner isolation surface 214 of the second polarity region 220 to couple the second polarity region 220 with the inner gasket 212.

The second polarity region 220 can include an outer portion 226, an inner portion 228, and a scored region 230. The scored region 230 can be disposed between the outer portion 226 and the inner portion 228. For example, the scored region 230 can separate the outer portion 226 from the inner portion 228. The scored region 230 can form a border between the outer portion 226 and the inner portion 228. The scored region 230 can be formed having a circular pattern, square pattern, an elliptical pattern, a triangular pattern, a rectangular pattern, a hexagonal pattern, or an octagonal pattern. The scored region 230 can be formed around an outer perimeter of the inner portion 228. The scored region 230 can be formed such that it does not completely separate the outer portion 226 from the inner portion 228. For example, the scored region 230 can be formed having a “C” shape. The scored region 230 can partially separate the outer portion 226 from the inner portion 228. For example, a tab region 229 can extend through the scored region 230 and between the outer portion 226 and the inner portion 228. The tab region 229 can correspond to a portion of the first surface 222 or the second surface 224 of the second polarity region 220 that has not been scored. The tab region 226 can couple the outer portion 226 with the inner portion 228.

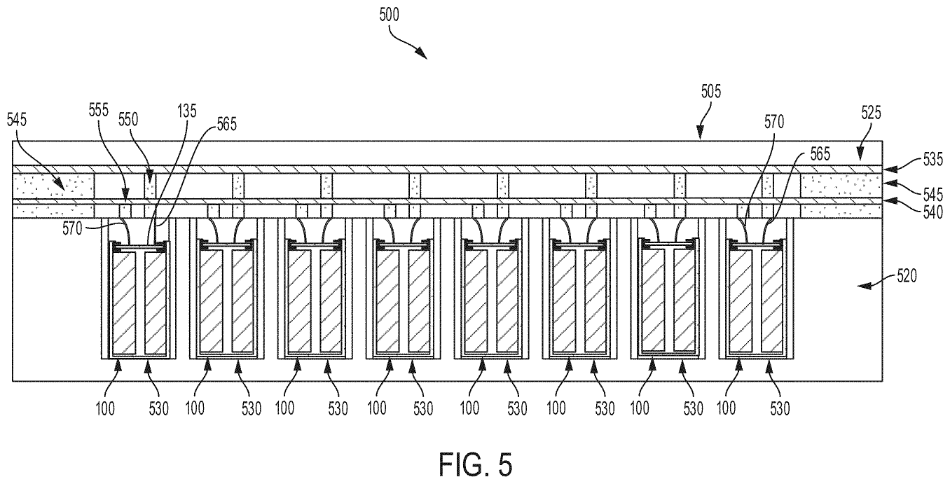

The scored region 230 can operate as a vent during a thermal event or over pressurization of the battery cell 100. Thus, the second polarity region 220 can correspond to a vent plate for the lid 135 and battery cell 100. For example, the scored region 230 can break an electrical connection between the battery cell 100 and a busbar of a battery pack (e.g., battery pack 505 of FIG. 5) in response to a thermal event or over pressurization of the battery cell 100. The tab region 229 can couple the inner portion 228 with the outer portion 226 to form a hinge point through the scored region 230. Therefore, in response to the scored region 230 breaking or cracking, the tab region 229 can turn into a hinge point to disconnect a coupling or connection between the inner portion 228 of the second polarity region 220 and an inner ring portion 248 of a fuse layer 240 of the lid 135. The tab region 229 can form the hinge point of the second polarity layer 220 when the scored region 230 breaks in response to a thermal event or over pressurization of the battery cell 100. The scored region 230 can correspond to a scored, thinned or otherwise structurally weakened region of the second polarity region 220. The scored region 230 can include a groove, divot or series of deformations formed into the first surface 222 or the second surface 224 of the second polarity region 220. The scored region 230 can be formed into the first surface 222 of the second polarity region 220. The scored region 230 can be formed into the second surface 224 of the second polarity region 220. The scored region 230 can be structurally weakened as compared to other regions or portions (e.g., outer portion 226, inner portion 228) of the second polarity region 220 to operate as a vent during a thermal event or over pressurization of a battery cell 100 the lid 135 is coupled with. For example, the scored region 230 can be structurally weakened as compared to other regions or portions of the second polarity region 220 to provide an electrical break point during a high voltage (e.g., over voltage) or high current (e.g., over current) conditions for a respective battery cell 100 the lid 135 is coupled with.

For example, the scored region 230 of the second polarity region 220 can break under high pressure, high voltage or high current conditions to break an electrical connection between the second polarity region 220 and a second polarity tab coupled with an electrolyte 130 within a battery cell 100. The scored region 230 of the second polarity region 220 can break under high pressure, high voltage or high current conditions to break an electrical connection between the second polarity region 220 and a busbar of a battery pack of an electric vehicle the second polarity region 220, and thus, the battery cell 100, is coupled with through one or more wire bonds. For example, the scored region 230 can operate or function as a current interrupter device (CID) for the battery cell 100 and break and electrical connection between at least one busbar of a battery pack of an electric vehicle and at least one layer (e.g., second polarity region 220) of the lid 135.

A thickness (e.g., vertical height) of the scored region 230 of the second polarity region 220 can be less than the thickness of other regions or portions of the second polarity region 220. For example, the first surface 222 of the second polarity region 220 can be scored to reduce a thickness of the scored region 230 as compared to the other regions or portions (e.g., outer portion 226, inner portion 228) of the second polarity region 220. The second surface 224 of the second polarity region 220 can be scored to reduce a thickness of the scored region 230 as compared to the other regions or portions (e.g., outer portion 226, inner portion 228) of the second polarity region 220. The second polarity region 220 can have a first thickness and the scored region 230 of the second polarity region 220 can have a second thickness. The first thickness of the second polarity region 220 can be different (e.g., less than) from the second thickness of the scored region 230. The other regions or portions (e.g., outer portion 226, inner portion 228) of the second polarity region 220, not including the scored region 230, can have a first thickness and the scored region 230 can have a second thickness. The second thickness of the scored region 230 can be less than the first thickness of the other regions or portions (e.g., outer portion 226, inner portion 228) of the second polarity region 220. The scored region 230 of the second polarity region 220 can have a width in a range from 0.1 mm to 2 mm (e.g., 0.4 mm). The width of the scored region 230 can vary within or outside this range. The scored region 230 can have a thickness (e.g., distance from an edge of the outer portion 226 to an edge of the inner portion 228) in a range from 1 mm to 6 mm (e.g., 3 mm). The thickness of the scored region 230 can vary within or outside this range.

The outer portion 226, the inner portion 228, and the tab region 229 can be formed form the same material. For example, the second polarity region can be formed from or can include electrically conductive material, such as a metallic material, aluminum, or an aluminum alloy with copper. The outer portion 226, the inner portion 228, and the tab region 229 can be formed form or include can include electrically conductive material, such as a metallic material, aluminum, or an aluminum alloy with copper. The second polarity region 220 can be formed having a circular shape, square shape, an elliptical shape, a triangular shape, a rectangular shape, a hexagonal shape, or an octagonal shape. The outer portion 226 and the inner portion 228 can be formed having a circular shape, square shape, an elliptical shape, a triangular shape, a rectangular shape, a hexagonal shape, or an octagonal shape. A width of the second polarity region 220 can range from 0.5 mm to 15 mm. The width of the second polarity region 220 can vary within or outside this range. A diameter of the second polarity region 220 can range from 12 mm to 25 mm. The diameter of the second polarity region 220 can vary within or outside this range. A diameter of the outer portion 226 (e.g., across entire second polarity region 220) can range from 12 mm to 25 mm. The diameter of the outer portion 226 can vary within or outside this range. A diameter of the inner portion 228 can range from 1 mm to 10 mm. The diameter of the inner portion 228 can vary within or outside this range.

The lid 135 can include an isolation layer 232. The isolation layer 232 can include a first surface 234 and a second surface 236. The isolation layer 232 can couple with the second polarity region 220. For example, the second surface 236 of the isolation layer 232 can couple with or contact with the first surface 222 of the second polarity region 220. The second surface 236 of the isolation layer 232 can couple with or contact with the first surface 222 of the outer portion 226 of the second polarity region 220. The isolation layer 232 can electrically isolate the second polarity region 220 from a fuse layer 240 of the lid 135. An adhesive layer or adhesive material can couple the isolation layer 232 with the second polarity region 220. For example, an adhesive layer or adhesive material can couple the isolation layer 232 with the outer portion 226 of second polarity region 220. The isolation layer 232 can be formed having a shape corresponding to the shape of the housing 105 of the battery cell 100. The isolation layer 232 can be formed having a shape corresponding to the shape of the outer portion 226 of the second polarity region 220. For example, the isolation layer 232 can be formed having a circular shape, square shape, an elliptical shape, a triangular shape, a rectangular shape, a hexagonal shape, or an octagonal shape. The isolation layer 232 can include non-conductive material, such as a polymer material, insulation material, plastic material, glass material, ceramic material or epoxy material.

The isolation layer 232 can include an orifice 238. The orifice 238 can include a hole or opening formed through the isolation layer 232. The orifice 238 can have a diameter in a range from 1 mm to 15 mm. The diameter of the orifice 238 can vary within or outside this range. The orifice 238 can be formed having a shape corresponding to the shape of the isolation layer 232. For example, the orifice 238 can be formed having a circular shape, square shape, an elliptical shape, a triangular shape, a rectangular shape, a hexagonal shape, or an octagonal shape. The isolation layer 232 can be formed having dimensions corresponding to the shape of the outer portion 226 of the second polarity region 220. For example, the isolation layer 232 can be disposed over or in contact with the outer portion 226 of the second polarity region 220 to electrically insulate the outer portion 226 of the second polarity region 220 from a fuse layer 240 of the lid 135. The isolation layer 232 can have a diameter (e.g., including orifice 238) in a range from 12 mm to 25 mm. The diameter of the isolation layer 232 can vary within or outside this range. The isolation layer 232 can have a thickness (e.g., length or distance from an outer edge of the isolation layer 232 to an inner edge of the orifice 238) in a range from 6 mm to 15 mm. The thickness of the isolation layer 232 can vary within or outside this range. The isolation layer 232 can have a width in a range from 0.5 mm to 15 mm. The width of the isolation layer 232 can vary within or outside this range.

The lid 135 can include a fuse layer 240. The fuse layer 240 can correspond to a fuse element or current interrupt component for the lid 135 and battery cell 100. For example, the fuse layer 240 can respond to an external short, short circuit, or mechanical deformity of the battery cell 100 by severing an electrical current path within the battery cell 100. The fuse layer 240 can include a first surface 242 (e.g., top surface) and a second surface 244 (e.g., bottom surface). The fuse layer 240 can include an outer ring portion 246 and an inner ring portion 248. The fuse layer 240 can couple with the isolation layer 232. For example, the second surface 244 of the fuse layer 240 can couple with or be in contact with the first surface 234 of the isolation layer 232. An adhesive layer or adhesive material can couple the fuse layer 240 with the isolation layer 232. For example, an adhesive layer or adhesive material can couple the outer ring portion 246 with the isolation layer 232. The outer ring portion 246 can be formed having a shape that corresponds to a shape to the housing 105 of the battery cell 100. The outer ring portion 246 can be formed having a shape that corresponds to a shape of the isolation layer 232. For example, the outer ring portion 246 can be formed having a circular shape, square shape, an elliptical shape, a triangular shape, a rectangular shape, a hexagonal shape, or an octagonal shape. The outer ring portion 246 can be symmetrical or asymmetrical. The inner ring portion 248 can be formed having a shape that corresponds to a shape to the housing 105 of the battery cell 100. The inner ring portion 248 can be formed having a shape that corresponds to a shape to the inner portion 228 of the second polarity region 220. For example, the inner ring portion 248 can be formed having a circular shape, square shape, an elliptical shape, a triangular shape, a rectangular shape, a hexagonal shape, or an octagonal shape. The inner ring portion 248 can be symmetrical or asymmetrical.

A tab region 250 can couple the inner ring portion 246 with the outer ring portion 248 of the fuse layer 240. For example, the tab region 250 can extend inwards from the outer portion 246 to the inner portion 248 of the fuse layer 240. A length of the tab region 250 can depend in part on the shape and size of the inner ring portion 248 and the outer ring portion 246 of the fuse layer 240. For example, the tab region 250 can extend along the shortest path (e.g., a straight line) between the inner ring portion 248 and the outer ring portion 246, such that the length of the tab region can be equal to the distance between inner ring portion 248 and the outer ring portion 246 of the fuse layer 240. The tab region 250 can couple the inner ring portion 246 with the outer ring portion 248 to form a hinge point for the fuse layer 240. For example, in response to external short or short circuit event, the tab region 250 can turn into a hinge point to break or otherwise disconnect a coupling, connection or electrical pathway between the inner ring portion 246 of the fuse layer 240 and the outer ring portion 248 of the fuse layer 240 of the lid 135.

The fuse layer 240 can be planar. For example, the outer ring portion 246 and the inner ring portion 248, and the tab region 250 can be flat components or flat layers that lie within a common plane. The inner ring portion 248 can be surrounded by or positioned within the outer ring portion 246 of the fuse layer 240. The inner ring portion 248 can be concentric with the outer ring portion 246. The inner portion 248 also can be arranged in other positions with respect to the outer ring portion 246, such that a center of the inner ring portion 248 may be offset from a center of the outer ring portion 246. Thus, the inner ring portion 248 may not be concentric with the outer ring portion 246 of the fuse layer 240. The outer ring portion 246 and the inner ring portion 248 can be formed having the same shape. The outer ring portion 246 can be formed having a different shape from inner ring portion 248.

The fuse layer 240 can include electrically conductive material, such as a metallic material, aluminum, or an aluminum alloy with copper, copper, or steel. For example, the fuse layer 240 can be formed from a rigid material, such as a metal or a rigid polymer. The fuse layer 240 can be used to carry electrical current. The outer ring portion 246 of the fuse layer 240 can have a diameter (e.g., a diameter across the fuse layer 240) in the range of 12 mm to 25 mm. millimeters to 25 millimeters. The diameter of the outer ring portion 246 of the fuse layer 240 can vary within or outside this range. The inner ring portion 248 of the fuse layer 240 can have a diameter in a range of 1 mm to 10 mm. The diameter of the inner ring portion 248 of the fuse layer 240 can vary within or outside this range. The tab region 250 of the fuse layer 240 can have a width in a range from 0.5 mm to 5 mm. The width of the tab region 250 can vary within or outside this range. The fuse layer 240 can have a thickness in a range from 0.1 mm to 1 mm. The thickness of the fuse layer 240 can vary within or outside this range.

The lid 135 can include an outer gasket 260. The outer gasket 260 can couple with the outer edge surface 207 of the first polarity region 205. For example, the outer gasket 260 can include an outer edge surface 262 and an inner edge surface 264. The inner edge surface 264 of the outer gasket can couple with or contact the outer edge surface 207 of the first polarity region 205. The outer gasket 260 can include an orifice 266. The orifice 266 can correspond to a hole or opening formed through the outer gasket 260. The first polarity region 205 can be disposed within the orifice 266 of the outer gasket 260. For example, the inner edge surface 264 of the outer gasket 260 can couple with or contact the outer edge surface 207 of the first polarity region 205 within the orifice 266. An adhesive material or adhesive layer can couple the outer gasket 260 with the first polarity region 205. For example, adhesive material or adhesive layer can couple the outer edge surface 207 of the outer gasket 260 with the outer edge surface 207 of the first polarity region 205.

The outer gasket 260 can be crimped on or portions of the outer gasket 260 can be bent over the first polarity region 205. For example, the outer gasket 260 can include a crimped edge 268. The crimped edge 268 can correspond to a top end or first end of the battery cell 100. The crimped edge 268 can be disposed over the outer edge surface 207 of the first polarity region 205. The crimped edge 268 can be disposed over portions of the first surface 206 of the first polarity region 205. For example, the crimped edge 268 can correspond to a surface or portion of the outer gasket that has been crimped over, bent over or otherwise formed over the outer edge surface 207 of the first polarity region 205 and portions of the first surface 206 of the first polarity region 205. The crimped edge 268 can extend over a portion of the first surface 206 of the first polarity region 205 in a distance in a range from 0.1 mm to 5 mm. The outer gasket 260 can couple with a first end 110 of the housing 105 of the battery cell 100 to seal the battery cell 100. For example, the seal formed between the outer gasket 260 and the first end 110 of the housing 105 can be a hermetic seal or fluid resistant seal, for example, so that the electrolyte 130 does not leak from its location within the housing 105. The coupling (e.g., crimped coupling, welded coupling) between the outer gasket 260 and the first end 110 of the housing 105 can form a hermetic seal, a fluid resistant seal, or a hermetic seal and a fluid resistant seal between the lid 135 and the housing 105.

The outer gasket 260 can include non-conductive material, such as a polymer material, insulation material, plastic material, glass material, ceramic material or epoxy material, polymer composite materials (e.g., combination of one or more of plastic material, glass material, ceramic material or epoxy material included in a polymer matrix). For example, the outer gasket 260 can electrically isolate the housing 105 of the battery cell 100 from the first polarity region 205 of the lid 135. The outer gasket 260 can be formed having a shape corresponding to the shape of the housing 105 of the battery cell 100. For example, the outer gasket 260 can be formed having a circular shape, square shape, an elliptical shape, a triangular shape, a rectangular shape, a hexagonal shape, or an octagonal shape. The orifice 266 of the outer gasket 260 can be formed having a shape corresponding to the shape of the outer gasket 260. For example, the orifice 266 can be formed having a circular shape, square shape, an elliptical shape, a triangular shape, a rectangular shape, a hexagonal shape, or an octagonal shape. A width (e.g., a distance from the outer edge surface 262 to the inner edge surface 264) of the outer gasket 260 can range from 5 mm to 20 mm. The width of the outer gasket 262 can vary within or outside this range. A thickness of the outer gasket 260 can range from 0.1 mm to 5 mm. The thickness of the outer gasket 260 can vary within or outside this range. A diameter of the outer gasket 260 (e.g., including orifice 266) can range from 12 mm to 30 mm. The diameter of the outer gasket 260 can vary within or outside this range. A diameter of the orifice 266 can range from 1 mm to 15 mm. The diameter of the orifice 266 can vary within or outside this range.

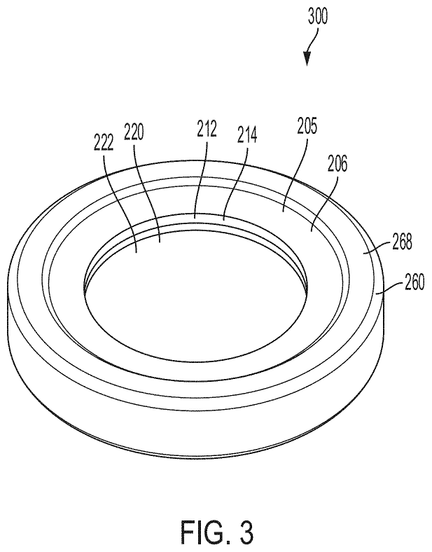

FIG. 3, among others, depicts a top view 300 of a lid 135 of a battery cell 100. The lid 135 includes the crimped edge 268 of the outer gasket 260 disposed over portions of the first surface 206 of the first polarity region 205. The first polarity region 205 is separated or electrically isolated from the second polarity region 220 by the inner gasket 212. For example, the inner isolation surface 214 of the inner gasket 212 can be disposed between the first polarity region 205 and the second polarity region 220. The inner isolation surface 214 of the inner gasket 212 can electrically isolate the first polarity region 205 from the second polarity region 220. The first polarity region 205 can form or correspond to a first polarity terminal of the battery cell 100. For example, the first polarity region 205 can form or correspond to a negative polarity region and form or correspond to a negative terminal of the battery cell 100. The first polarity region 205 can form or correspond to a positive polarity region and form or correspond to a positive terminal of the battery cell 100. The first surface 206 of the first polarity region 205 can form or correspond to a first polarity terminal of the battery cell 100. For example, a first polarity wirebond can include a first end coupled with the first surface 206 of the first polarity region 205 and a second end coupled with a first polarity busbar of a battery pack of an electric vehicle.

The second polarity region 220 can form or correspond to a second polarity terminal of the battery cell 100. For example, the second polarity region 220 can form or correspond to a positive polarity region and form or correspond to a positive terminal of the battery cell 100. The second polarity region 220 can form or correspond to a negative polarity region and form or correspond to a negative terminal of the battery cell 100. The first surface 222 of the second polarity region 220 can correspond to a second polarity terminal of the battery cell 100. For example, a second polarity wirebond can include a first end coupled with the first surface 220 of the second polarity region 220 and a second end coupled with a second polarity busbar of a battery pack of an electric vehicle. Thus, the battery cells 100 as described herein can include both the positive terminal and the negative terminal disposed at a same lateral end (e.g., the top end) of the battery cell 100. For example, the lid 135 can provide a first polarity terminal (e.g., negative terminal, first polarity region 205) for the battery cell 100 at the first end 110 and a second polarity terminal (e.g., positive terminal, second polarity region 220) for the battery cell 100 at the first end 110. Having both terminals, for the positive and the negative terminals on one end of the battery cell 100 can eliminate wire bonding to one side of the battery pack and welding of a tab to another side of the battery cell 100 (e.g., the bottom end or the crimped region). The housing 105 of the battery cell 100 can be formed from electrically non-conductive material (e.g., non-polarized material. In this manner, a terminal or an electrode tab along the bottom of the battery cell 100 can be eliminated from the structure. Thus, improving the pack assembly process by making it easier to bond the wire to each of the first polarity terminal (e.g., negative terminal) and the second polarity terminal (e.g., positive terminal) of the battery cell 100.

The lid 135 can be formed having a compact or smaller design to provide for more room for active material within the battery cell 100. For example, the battery cells 100 as described herein include a lid 135 having layers that can operate as a current interrupter in response to a short circuit event, thermal event or over pressurization of the battery cell 100. Thus, the battery cells 100 as described can be formed no having a separate current interrupter device (CID) or distinct current interrupter device (e.g., separate from the lid). As a separate current interrupter device is not included, more room within the housing 205 of the battery cell 100 can be provided for electrolyte material 130, active material, or jelly-roll material. For example, a height of electrolyte 130 material, active material or a jelly-roll disposed within the housing 105 of the battery cell 100 can be increased by 0.5 mm to 2 mm (e.g., 1 mm) using the lid 135 and battery cell 100 as described herein.

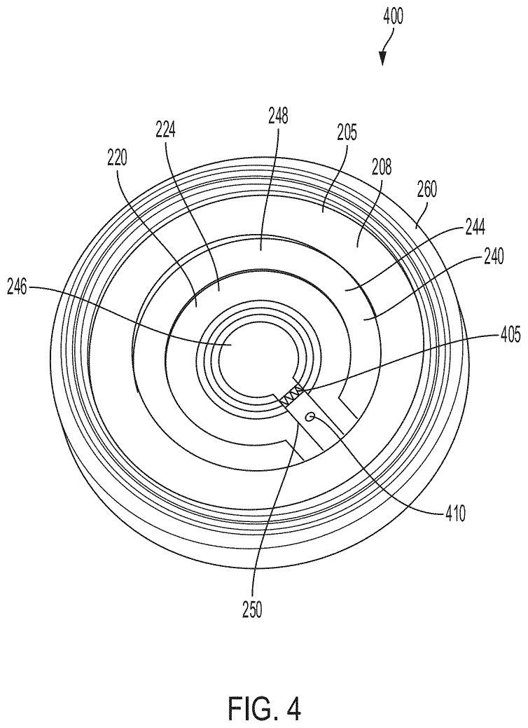

FIG. 4, among others, depicts a bottom view 400 of a lid 135 of a battery cell 100. In particular, FIG. 4 shows the second surfaces (e.g., bottom surfaces) of different layers of the lid 135. For example, view 400 shows the second surface 208 of the first polarity region 205 (e.g., negative polarity region) and the second surface 224 of the second polarity region 220 (e.g., positive polarity region). The second surface 244 of the fuse layer 240 is disposed between the first polarity region 205 and the second polarity region 220. For example, the fuse layer 240 includes the outer ring portion 248 and the inner ring portion 246. The outer ring portion 248 is disposed between the second surface 208 of the first polarity region 205 and the second surface 224 (or portions of) of the second polarity region 220. The outer ring portion 248 can be spaced from or electrically isolated from the second surface 224 of the second polarity region 220 by an isolation layer (e.g., isolation layer 232 of FIG. 2). The second surface 208 of the first polarity region 205 can couple with a first polarity portion of an electrolyte 130 disposed within a battery cell 100. For example, a first polarity tab (e.g., negative tab) can couple a first polarity region of the electrolyte 130 with the second surface 208 of the first polarity region 205 to form a first polarity surface area (e.g., negative surface area) on the lid 135 for first polarity wire bonding. The first surface 206 or the second surface 208 of the first polarity region 205 can correspond to a first polarity layer or first polarity region of the lid 135.

The second surface 224 of the second polarity region 220 can couple with a second polarity portion of an electrolyte 130 disposed within a battery cell 100. For example, a second polarity tab (e.g., positive tab) can couple a second polarity region of the electrolyte 130 (e.g., positive region of electrolyte 130) with the second surface 224 of the second polarity region 220 to form a second polarity surface area (e.g., positive surface area) on the lid 135 for second polarity wire bonding. The first surface 222 or the second surface 224 of the second polarity region 220 can correspond to a second polarity layer or second polarity region of the lid 135. The inner ring portion 246 of the fuse layer 240 can contact, couple with or be disposed over portions of the second surface 224 of the second polarity region 220. For example, the inner ring portion 246 can contact, couple with or be disposed over an inner portion 228 of the second polarity region 240. The inner ring portion 246 can electrically connect with or form an electrical path between the second polarity region 220 and the fuse layer 240.

The fuse layer 240 includes the tab region 250 that forms or provides an electrical path between the inner ring portion 246 and the outer ring portion 248 of the fuse layer. The tab portion 250 couples the inner ring portion 246 with the outer ring portion 248. The tab portion 250 can be formed in a variety of different shapes. The tab portion 250 can have a square shape, a rectangular shape or a non-linear shape. For example, the tab portion 250 can be formed having a curved shape or have curved edges. The fuse layer 240 can correspond to a fuse element or current interrupt component for the lid 135 and battery cell 100 and break or sever an electrical current path within the battery cell 100 in response to an external short, short circuit, or mechanical deformity of the battery cell 100. For example, under normal operating conditions, the fuse layer 240 can provide an electrical path for current to flow between the electrolyte 130 (e.g., electrolyte material) within the housing 105 of the battery cell 100 and the second polarity region 220 of the lid 135. The current path between the electrolyte 130 and the second polarity region 220 can pass or flow from the inner ring portion 246, through the tab region 250, to the outer ring portion 248. The current path between the electrolyte 130 and the second polarity region 220 can also pass in the opposite direction (e.g., from the outer ring portion 248, through the tab region 250, to the inner portion 246). The tab region 250 can carry electrical current in either direction between the outer ring portion 248 and the inner ring portion 246 of the fuse layer 240.

When the current inside the battery cell 100 reaches a threshold value (e.g., a value that may be indicative of a short circuit or thermal runaway) or when the battery cell 100 is subjected to crushing or other mechanical deformation, the tab region 250 can tear, sever, melt, or otherwise deform in a manner that disconnects the current path between the inner ring portion 246 and the outer ring portion 248 of the fuse layer 240. The tab region 250 can include various features to facilitate this functionality. For example, the tab region 250 can include a scored portion 405, which can be or can include one or more scoring marks, scoring lines, or scoring patterns. The scored portion 405 can weaken at least a portion of the material of the tab region 250 in the vicinity of the scored portion 405, to facilitate tearing or rupturing of the tab region 250 in the event that mechanical stress within the battery cell 100 reaches a threshold value.

The scored portion 405 can define one or more seems on the tab region 250 of the fuse layer 240, and the tab region 250 can tear or break along these seems in response to mechanical stress, such as mechanical stress that occurs as a result of the battery cell 100 being crushed. The scored portion 405 can include one or more scoring marks arranged in a linear pattern, a circular pattern, a star-shaped pattern, a hatched pattern, a symmetrical or asymmetrical pattern, or any other pattern configured to facilitate tearing or breaking of the tab region 250 in response to a predetermined mechanical stress threshold. The scored portion 405 can be formed, for example, by removing some of the material of the tab region 250. For example, the scored portion 405 can include a groove, a series of divots or cuts formed into a surface of the tab region 250. The scored portion 405 can include a partial cutting, etching, ablation, or other removal of some of the material that forms the tab region 250. Thus, a thickness of the scored portion 405 may be less than a thickness of the remainder of the tab region 250. For example, the scored portion 405 may have a thickness in range that is less than 10% to less than 90% of the thickness of a remainder (e.g., a non-scored portion) of the tab region 250.

The mechanical stress threshold selected to cause tearing or breaking of the tab region 250 at the scored portion 405 can be based at least in part on a percentage of deformation of the battery cell 100. For example, the scored portion 405 can be selected to cause the tab region 250 to break when the battery cell 100 deforms by at least 30%. Stated differently, the scoring pattern 405 can be selected to cause the tab region 250 to break when the battery cell 100 is crushed or otherwise subjected to an external force such that its height is reduced by at least 30%. The scored portion 405 can also be selected to cause the tab region 250 to break at other deformation thresholds of the battery cell 100. For example, the scored portion 405 can be selected to cause the tab region 250 to break when the battery cell 100 deforms in a range by at least 5% to at least 75%, or more.

The tab region 250 can also include one or more holes 410. The hole 410 can be any opening, aperture, perforation, or other absence of material that forms an opening along at least a portion of the tab region 250. The tab region 250 can serve as part of a current path within the battery cell 100. As current passes through tab region 250, the temperature of the tab region 250 can rise due to resistive heating. The effects of resistive heating can be inversely proportional to the cross-sectional area of the tab region 250. As a result, the tab region 250 can experience a larger amount of resistive heating in region where the hole 410 is formed, because the cross-sectional area of the tab region 250 in this region is smaller due to the removal of material to form the hole 410. This can allow the tab region 250 to serve as a fuse. In particular, the hole 410 can define a fuse region of the tab region 250 that can melt or otherwise break due to resistive heating in response to a threshold current level passing through the tab region 250. Because the tab region 250 serves as a portion of the current path for the battery cell 100, the current level at which the leg melts or breaks can be an upper limit for current flowing in the battery cell 100. The current level at which the tab region 250 region breaks can depend on a size of the hole 410 relative to the size of the tab region 250. For example, the hole 410 can be selected to have a size such that a distance between an edge of the hole 410 and an outer edge of the tab region 250 is between 0.05 mm and 1 mm. The hole 410 can be formed having a circular shape, square shape, an elliptical shape, a triangular shape, a rectangular shape, a hexagonal shape, or an octagonal shape. The hole 410 can be formed having an irregular or non-polygonal shape. The hole 410 can be spaced away from the scored portion 405 of the tab region 250. The hole 410 can be centered between opposing edges of the tab region 250, or may be offset from the center of tab region 250. The hole 410 can be positioned such that the hole 410 at least partially overlaps with the scored region 405. For example, the scored region 405 may include one or more scoring marks formed along an edge of the hole 410. The threshold current that triggers the tab region 250 of the fuse layer 240 to melt or break can be in a range between 10A and 100 A. The threshold current that triggers the tab region 250 of the fuse layer 240 to melt or break can also be less than 10 A or greater than 100 A.

FIG. 5 depicts a cross-section view 500 of a battery pack 505 to hold at least one battery cell 100. For example, the battery pack 505 can include battery cells 100 having a lid 135 that includes a fuse layer 240, a first polarity region 205 and a second polarity region 220. The battery cell 100 can be disposed in a battery pack 505 having multiple battery cells 100. The battery pack 505 can include a single battery cell 100 having a lid 135 that includes a fuse layer 240, a first polarity region 205 and a second polarity region 220. The battery pack 505 can include multiple battery cells 100 having a lid 135 that includes a fuse layer 240, a first polarity region 205 and a second polarity region 220. The battery cells 100 can have an operating voltage in a range from 2.5 V to 5 V (e.g., 2.5 V to 4.2 V). The operating voltage of the battery cell 100 can vary within or outside this range. The battery pack 505 can include a battery case 520 and a capping element 525. The battery case 520 can be separated from the capping element 525. The battery case 520 can include or define a plurality of holders 530. Each holder 530 can include a hollowing or a hollow portion defined by the battery case 520. Each holder 530 can house, contain, store, or hold a battery cell 100. The battery case 520 can include at least one electrically or thermally conductive material, or combinations thereof. The battery case 520 can include one or more thermoelectric heat pumps. Each thermoelectric heat pump can be thermally coupled directly or indirectly to a battery cell 100 housed in the holder 530. Each thermoelectric heat pump can regulate temperature or heat radiating from the battery cell 100 housed in the holder 530. The first bonding element 565 and the second bonding element 570 can extend from the battery cell 100 through the respective holder 530 of the battery case 520. For example, the first bonding element 365 or the second bonding element 570 can couple with the first polarity region 205 of the lid 135 or the second polarity region 220 of the lid 135.

Between the battery case 520 and the capping element 525, the battery pack 505 can include a first busbar 535, a second busbar 540, and an electrically insulating layer 545. The first busbar 535 and the second busbar 540 can each include an electrically conductive material to provide electrical power to other electrical components in the electric vehicle. The first busbar 535 (e.g., a first current collector) can be connected or otherwise electrically coupled to the first bonding element 565 extending from each battery cell 100 housed in the plurality of holders 530 via a bonding element 550. The bonding element 550 can include electrically conductive material, such as a metallic material, aluminum, or an aluminum alloy with copper. The bonding element 550 can extend from the first busbar 535 to the first bonding element 565 extending from each battery cell 100. The bonding element 550 can be bonded, welded, connected, attached, or otherwise electrically coupled to the first bonding element 565 extending from the battery cell 100. The first bonding element 565 can define the first polarity terminal for the battery cell 100. The first bonding element 565 can include a first end coupled with a surface of the lid 135 (e.g., first polarity region 205, second polarity region 220) and a second end coupled with a surface of the bonding element 550. The first busbar 535 can define the first polarity terminal for the battery pack 505. The second busbar 540 (e.g., a second current collector) can be connected or otherwise electrically coupled to the second bonding element 570 extending from each battery cell 100 housed in the plurality of holders 530 via a bonding element 555. The bonding element 555 can include electrically conductive material, such as a metallic material, aluminum, or an aluminum alloy with copper. The bonding element 555 can extends from the second busbar 540 to the second bonding element 570 extending from each battery cell 100. The bonding element 555 can be bonded, welded, connected, attached, or otherwise electrically coupled to the second bonding element 570 extending from the battery cell 100. The second bonding element 570 can define the second polarity terminal for the battery cell 100. The second bonding element 570 can include a first end coupled with a surface of the lid 135 (e.g., first polarity region 205, second polarity region 220) and a second end coupled with a surface of the bonding element 555. The second busbar 540 can define the second polarity terminal for the battery pack 505.

The first busbar 535 and the second busbar 540 can be separated from each other by the electrically insulating layer 545. The electrically insulating layer 545 can include any electrically insulating material or dielectric material, such as air, nitrogen, sulfur hexafluoride (SF6), porcelain, glass, and plastic (e.g., polysiloxane), among others to separate the first busbar 535 from the second busbar 540. The electrically insulating layer 345 can include spacing to pass or fit the first bonding element 565 connected to the first busbar 535 and the second bonding element 570 connected to the second busbar 540. The electrically insulating layer 545 can partially or fully span the volume defined by the battery case 520 and the capping element 525. A top plane of the electrically insulating layer 545 can be in contact or be flush with a bottom plane of the capping element 525. A bottom plane of the electrically insulating layer 545 can be in contact or be flush with a top plane of the battery case 520.

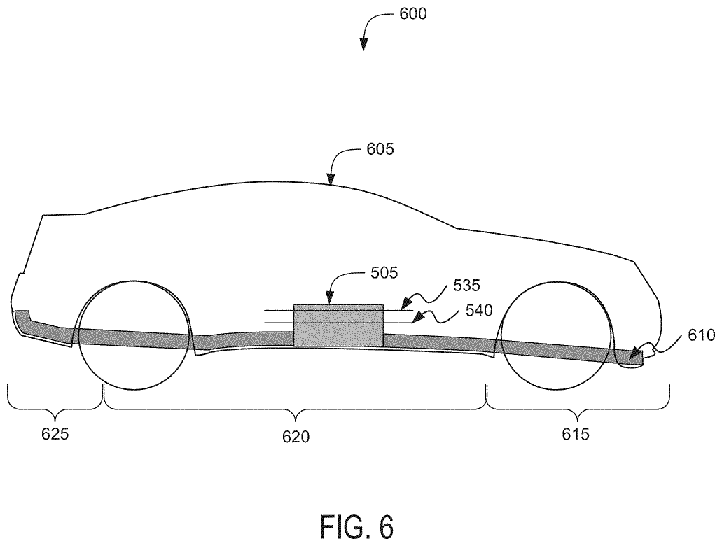

FIG. 6 depicts a cross-section view 600 of an electric vehicle 605 installed with a battery pack 505. The battery pack 505 can include at least one battery cell 100 having a lid 135 that includes a fuse layer 240, a first polarity region 205 and a second polarity region 220. The battery cells 100 described herein can be used to form battery packs 505 residing in electric vehicles 605 for an automotive configuration. For example, the battery cell 100 can be disposed in the battery pack 505 and the battery pack 505 can be disposed in the electric vehicle 605. An automotive configuration includes a configuration, arrangement or network of electrical, electronic, mechanical or electromechanical devices within a vehicle of any type. An automotive configuration can include battery cells for battery packs in vehicles such as electric vehicles (EVs). EV s can include electric automobiles, cars, motorcycles, scooters, passenger vehicles, passenger or commercial trucks, and other vehicles such as sea or air transport vehicles, planes, helicopters, submarines, boats, or drones. EVs can be fully autonomous, partially autonomous, or unmanned. Thus, the electric vehicle 605 can include an autonomous, semi-autonomous, or non-autonomous human operated vehicle. The electric vehicle 605 can include a hybrid vehicle that operates from on-board electric sources and from gasoline or other power sources. The electric vehicle 605 can include automobiles, cars, trucks, passenger vehicles, industrial vehicles, motorcycles, and other transport vehicles. The electric vehicle 605 can include a chassis 610 (e.g., a frame, internal frame, or support structure). The chassis 610 can support various components of the electric vehicle 605. The chassis 610 can span a front portion 615 (e.g., a hood or bonnet portion), a body portion 620, and a rear portion 625 (e.g., a trunk portion) of the electric vehicle 605. The front portion 615 can include the portion of the electric vehicle 605 from the front bumper to the front wheel well of the electric vehicle 605. The body portion 620 can include the portion of the electric vehicle 605 from the front wheel well to the back wheel well of the electric vehicle 605. The rear portion 625 can include the portion of the electric vehicle 605 from the back wheel well to the back bumper of the electric vehicle 605.

The battery pack 605 that includes at least one battery cell 100 having a lid 135 that includes a fuse layer 240, a first polarity region 205 and a second polarity region 220 can be installed or placed within the electric vehicle 605. For example, the battery pack 505 can couple with a drive train unit of the electric vehicle 605. The drive train unit may include components of the electric vehicle 605 that generate or provide power to drive the wheels or move the electric vehicle 605. The drive train unit can be a component of an electric vehicle drive system. The electric vehicle drive system can transmit or provide power to different components of the electric vehicle 605. For example, the electric vehicle drive train system can transmit power from the battery pack 505 to an axle or wheels of the electric vehicle 605. The battery pack 505 can be installed on the chassis 610 of the electric vehicle 605 within the front portion 615, the body portion 620 (as depicted in FIG. 6), or the rear portion 625. A first busbar 535 (e.g., first polarity busbar) and a second busbar 540 (e.g., second polarity busbar) can be connected or otherwise be electrically coupled with other electrical components of the electric vehicle 605 to provide electrical power from the battery pack 505 to the other electrical components of the electric vehicle 605. For example, the first busbar 535 can couple with at least one surface of a battery cell 100 (e.g., first polarity region 205 of the id 135) of the battery pack 505 through a wirebond or bonding element (e.g., bonding element 550 of FIG. 5). The second busbar 540 can couple with at least one surface of a battery cell 100 (e.g., second polarity region 220 of the lid 135) of the battery pack 505 through a wirebond or bonding element (e.g., bonding element 555 of FIG. 5).

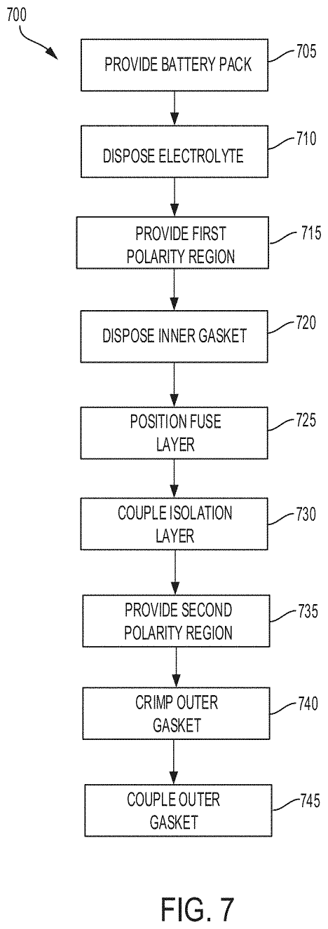

FIG. 7, among others, depicts a flow diagram of a method 700 of providing a battery cell 100 of a battery pack 505 to power an electric vehicle 605. The method 700 can include providing a battery pack 505 (ACT 705). For example, the method 700 can include providing a battery pack 505 having a battery cell 100. The battery cell 100 can include a housing 105 that includes a first end 110 and a second end 115. The housing 105 can be formed having or defining an inner region 120. The battery cell 100 can be a lithium ion battery cell, a nickel-cadmium battery cell, or a nickel-metal hydride battery cell. The battery cell 100 can be part of a battery pack 505 installed within a chassis 610 of an electric vehicle 605. For example, the battery cell 100 can be one of multiple battery cells 100 disposed within a battery pack 505 of the electric vehicle 605 to power the electric vehicle 605. The housing 105 can be formed from a cylindrical casing with a circular, ovular, elliptical, rectangular, or square base or from a prismatic casing with a polygonal base.

The method 700 can include disposing an electrolyte 130 (ACT 710). For example, method 700 can include disposing an electrolyte 130 in the inner region 120 defined by the housing 105. The electrolyte 130 can be disposed in the inner region 120 defined by the housing 105 of the battery cell 100. A single electrolyte 130 can be disposed within the inner region 120 or multiple electrolytes 130 (e.g., two or more) can be disposed within the inner region 120. The electrolytes 130 can be positioned within the inner region 120 such that they are spaced evenly from each other. For example, the electrolytes 130 can be positioned within the inner region 120 such that they are not in contact with each other. One or more insulation materials 140 may be disposed between different electrolytes 130 within the same or common inner region 120. The electrolytes 130 can be positioned within the inner region 120 such that they are spaced a predetermined distance from an inner surface of the housing 105. For example, insulation materials 140 may be disposed between different inner surfaces of the housing 105 and the electrolytes 130 within the inner region 120 to insulate the housing 105 from the electrolytes 130. Thus, a distance the electrolytes 130 are spaced from the inner surface of the housing 105 can correspond to a thickness of the insulation materials 140. An insulation material 140 can electrically insulate portions or surfaces of a lid 135 from the electrolyte 130. The insulation material 140 can be disposed over a top surface of the electrolyte 130 such that the insulation material 140 is disposed between the electrolyte 130 and portions of the lid 135.

The method 700 can include providing a first polarity region 205 having an inner edge surface 209 and an outer edge surface 207 (ACT 715). For example, a first polarity region 205 can be formed from an electrically conductive material (e.g., aluminum) to form a first polarity region for the battery cell 100. The first polarity region 205 can be formed having a shape corresponding to the housing 105 of the battery cell 100. For example, the first polarity region 205 can be formed having a circular shape, square shape, an elliptical shape, a triangular shape, a rectangular shape, a hexagonal shape, or an octagonal shape. An orifice 210 can be formed through the first polarity region 205. The orifice 210 can provide a hole or opening through the first polarity region 205. The inner edge surface 209 can form a wall or border of the orifice 210. The first polarity region 205 having the orifice 210 can form a ring shape, cup shape, donut shape or the similar. The shape of the first polarity region 205 can be selected to receive or dispose within other layers of a lid 135 of the battery cell 100.

The method 700 can include disposing an inner gasket 212 within the inner edge surface 209 of the first polarity region 205 (ACT 720). The inner gasket 212 can have an inner isolation surface 214. For example, the inner gasket 212 can be disposed within the orifice 210 of the first polarity region 205 such that an outer isolation surface 216 of the inner gasket 212 couples with or is in contact with the inner edge surface 209 of the first polarity region 205. Disposing an inner gasket 212 can include providing an adhesive layer or adhesive material over the outer edge surface 216 of the inner gasket 212 or over the inner edge surface 209 of the first polarity region 205. For example, an adhesive layer or adhesive material can couple the outer isolation surface 216 of the inner gasket 212 with the inner edge surface 209 of the first polarity region 205. The outer isolation surface 216 of the inner gasket 212 may couple with the inner edge surface 209 of the first polarity region 205 through a welded connection (e.g., spot weld). The inner gasket 212 can be formed having a shape corresponding to the shape of the first polarity region 205. For example, the inner gasket 212 can be formed having a circular shape, square shape, an elliptical shape, a triangular shape, a rectangular shape, a hexagonal shape, or an octagonal shape. An orifice 218 can be formed through the inner gasket 212. For example, the orifice 218 can include an opening or hole formed through the inner gasket 212. The inner isolation surface 214 can form a wall or border of the orifice 218. The inner gasket 212 having the orifice 218 can form a ring shape, cup shape, donut shape or the similar. The shape of the inner gasket 212 can be selected to receive or dispose within other layers of a lid 135 of the battery cell 100. The inner gasket 212 can be formed from non-conductive material to electrically isolate or insulate one or more layers (e.g., fuse layer 240, second polarity region 220) of the lid 135 from the first polarity region 205. For example, the inner gasket 212 can be positioned between one or more layers (e.g., fuse layer 240, second polarity region 220) of the lid 135 and the first polarity region 205 to provide electrical isolation or insulation.

The method 700 can include positioning a fuse layer 240 within the inner isolation surface 214 of the inner gasket 212 (ACT 725). The fuse layer 240 can include a first surface 242 and a second surface 244. The fuse layer 240 can couple with the inner isolation surface 214 of the inner gasket 212 through an adhesive layer or adhesive material. For example, an adhesive layer or adhesive material can be disposed over the inner isolation surface 214 of the inner gasket 212 or over an outer edge surface 245 of the fuse layer 240. The adhesive layer or adhesive material can couple the inner isolation surface 214 of the inner gasket 212 with the outer edge surface 245 of the fuse layer 240. The fuse layer 240 can be formed having a shape corresponding to the shape of the inner gasket 212 and the orifice 218 of the inner gasket 212. For example, the fuse layer 240 can be formed having a circular shape, square shape, an elliptical shape, a triangular shape, a rectangular shape, a hexagonal shape, or an octagonal shape. The fuse layer 240 can correspond to a fuse element or current interrupt component for the lid 135 and battery cell 100. For example, the fuse layer 240 can form an electrical pathway to the second polarity region 220. The fuse layer 240 can respond to an external short, short circuit, or mechanical deformity of the battery cell 100 by severing an electrical current path within the battery cell 100. The fuse layer 240 can include an outer ring portion 246 and an inner ring portion 248. The outer ring portion 246 can couple with the inner ring portion through a tab region 250. The tab region 250 can be formed to extend from the outer portion 246 to the inner portion 248 of the fuse layer 240. Thus, a length of the tab region 250 can depend in part on the shape and size of the inner portion 248 and the outer portion 246 of the fuse layer 240. The tab region 250 can be formed having a length that corresponds to the shortest path (e.g., a straight line) between the inner ring portion 248 and the outer ring portion 246. The tab region 250 can be formed as a hinge point between the inner ring portion 246 and the outer ring portion 248. For example, in response to external short or short circuit event, the tab region 229 can turn into a hinge point to break or otherwise disconnect a coupling, connection or electrical pathway between the inner ring portion 248 of the fuse layer 240 and the outer ring portion 246 of the fuse layer 240 of the lid 135.

The method 700 can include coupling a first surface 234 of an isolation layer 232 with the second surface 244 of the fuse layer 240 (ACT 730). The isolation layer 232 can include the first surface 234 and a second surface 236. The isolation layer 232 can be disposed over portion of the fuse layer 240 to electrically isolate or insulate the portions (e.g., second polarity region 220) of the fuse layer 240 from other layers of the lid 135. For example, the first surface 234 of the isolation layer 232 can couple with the outer portion 248 of the fuse layer 240. The isolation layer 232 can be formed from non-conductive material to electrically isolate or insulate the portions (e.g., second polarity region 220) of the fuse layer 240 from other layers of the lid 135. The isolation layer 232 can be formed having a shape corresponding to a shape of the outer portion 248 of the fuse layer 240. For example, the isolation layer 232 can be formed having a ring shape, cup shape or donut shape and include an orifice 238. The isolation layer 232 can be formed having similar dimensions, such as a thickness of the outer ring portion 246. The isolation layer 232 can couple with the outer ring portion 246 of the fuse layer 240 such that the isolation layer 232 is disposed over the outer ring portion 246 and not disposed over or covering the inner ring portion 246 of the fuse layer 240. The isolation layer 232 can couple with the fuse layer 240 through an adhesive layer or adhesive material. For example, an adhesive layer or adhesive material can be disposed over the first surface 234 of the isolation layer 232 or over the outer ring portion 246 of the fuse layer 240 to couple the isolation layer 232 with the fuse layer 240.

The method 700 can include providing a second polarity region 220 having a first surface 222 and a second surface 224 (ACT 735). Providing the second polarity region 220 can include coupling the first surface 222 of the second polarity region 220 with the second surface 236 of the isolation layer 232 such that the isolation layer 232 can be disposed between the second surface 244 of the fuse layer 240 and the first surface 222 of the second polarity region 220. An adhesive layer or adhesive material can be disposed over the first surface 222 of the second polarity region 220 or over the second surface 236 of the isolation layer 232 to couple the second polarity region 220 with the isolation layer 232. The second polarity region 220 can form a second polarity terminal for the lid 135 and thus, the battery cell 100. For example, the second polarity region can be formed from conductive material. The second polarity 220 can couple with a second polarity portion of the electrolyte 130 disposed within the housing 105 of the battery cell 100. Providing the second polarity region 220 can include disposing the second polarity region 220 within the inner gasket 212. For example, the second polarity region 220 can be disposed within or couple with the inner gasket 212 such that the outer edge 225 of the second polarity region 220 couples with or is in contact with the inner isolation surface 214 of the second polarity region 220.

Providing the second polarity region 220 can include forming an outer portion 226, an inner portion 228, and a scored region 230 on the second polarity region 220. The scored region 230 can be disposed between the outer portion 226 and the inner portion 228. For example, the scored region 230 can separate the outer portion 226 from the inner portion 228. The scored region 230 can be formed having a “C” shape. For example, the scored region 230 can be formed such that it partially separates the outer portion 226 from the inner portion 228. The scored region 230 can be formed to operate as a vent during a thermal event or over pressurization of the battery cell 100. For example, the second polarity region 220 can correspond to a vent plate for the lid 135 and battery cell 100. The scored region 230 can be formed and shaped to break an electrical connection between the battery cell 100 and a busbar of a battery pack 505 in response to a thermal event or over pressurization of the battery cell 100. Forming the scored region 230 can include forming a scored, thinned or otherwise structurally weakened region of the second polarity region 220. For example, the scored region 230 can include a groove, divot or series of deformations formed into the first surface 222 or the second surface 224 of the second polarity region 220. The second polarity region 220 can be formed having a shape correspond to the shape of the inner gasket 212, the isolation layer 232, or the fuse layer 240. For example, the second polarity region 220 can be formed having a circular shape, square shape, an elliptical shape, a triangular shape, a rectangular shape, a hexagonal shape, or an octagonal shape.

The method 700 can include crimping an outer gasket 260 on the outer edge surface 207 of the first polarity region 205 to form a lid 135 for the battery cell 100 (ACT 740). The lid 135 can include an outer gasket 260 that forms an outer border of the lid 135. The outer gasket 260 can be formed over or disposed over portions of the first polarity region 205 to electrically isolate or insulate the housing 105 of the battery cell 100 from the first polarity region 205. For example, coupling the outer gasket 260 can include crimping, bending or otherwise manipulating an edge surface or outer surface of the outer gasket 260 over at least one surface (e.g., side surface, top surface) of the first polarity region 205. Crimping the outer gasket 260 can include crimping or bending a top end or first end of the outer gasket 260 over the outer edge surface 207 of the first polarity region 205. Crimping the outer gasket 260 can include crimping or bending a top end or first end of the outer gasket 260 over portions of the first surface 206 of the first polarity region 205. Thus, crimping the outer gasket 260 can include forming a crimped edge 268 of the outer gasket 260. The crimped edge 268 can correspond to a surface or portion of the outer gasket that has been crimped over, bent over or otherwise formed over the outer edge surface 207 of the first polarity region 205 and portions of the first surface 206 of the first polarity region 205. The outer gasket 260 can be formed having an outer edge surface 262 and an inner edge surface 264. The inner edge surface 264 of the outer gasket can couple with or contact the outer edge surface 207 of the first polarity region 205. An orifice 266 can be formed through the outer gasket 260. The orifice 266 can correspond to a hole or opening formed through the outer gasket 260. The first polarity region 205 can be disposed within the orifice 266 of the outer gasket 260. An adhesive material or adhesive layer can couple the outer gasket 260 with the first polarity region 205. For example, adhesive material or adhesive layer can couple the outer edge surface 207 of the outer gasket 260 with the outer edge surface 207 of the first polarity region 205.

The method 700 can include coupling the outer gasket 260 with the first end 110 of the housing 105 to seal the battery cell 100 (ACT 745). Coupling the outer gasket 260 can include crimping or welding the outer gasket 260 with the first end 110 of the housing 105. The outer gasket 260 can contact and couple with at least one surface of the first end 110 of the housing 105 to seal the battery cell 100. For example, the coupling between the outer gasket 260 and the first end 110 of the housing 105 can form a hermetic seal or fluid resistant seal, for example, so that the electrolyte 130 does not leak from its location within the housing 105. The coupling (e.g., crimped coupling, welded coupling) between the outer gasket 260 and the first end 110 of the housing 105 can form a hermetic seal, a fluid resistant seal, or a hermetic seal and a fluid resistant seal between the lid 135 and the housing 105. The outer gasket 260 can be positioned between the first end 110 of the housing 105 and the first polarity region 205 to electrically isolate the first end 110 of the housing 105 from the first polarity region 205. The outer gasket 260 can be formed from non-conductive material.

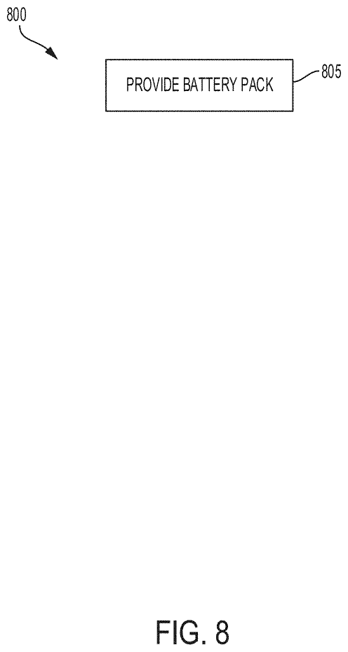

FIG. 8 depicts a method 800. The method 800 can include providing a battery pack 505 having at least one battery cell 100 for electric vehicles 605 (ACT 805). The battery pack 505 can include at least one battery cell 100. The battery cell 100 can include a housing 105 having a first end 110 and a second end 115. The housing 105 can define an inner region 120. An electrolyte 130 can be disposed in the inner region 120 defined by the housing 105. A lid 135 can couple with a first end 110 of the housing 105. The lid 135 can include a first polarity region 205 having an inner edge surface 209 and an outer edge surface 207. The lid 135 can include an inner gasket 212 disposed within the inner edge surface 209 of the first polarity region 205. The inner gasket 212 can have an inner isolation surface 214. The lid 135 can include a fuse layer 240 disposed within the inner isolation surface 214 of the inner gasket 212. The fuse layer 240 can have a first surface 242 and a second surface 244. The lid 135 can include an isolation layer 232 having a first surface 234 and a second surface 236. The first surface 234 of the isolation layer 232 can couple with the second surface 244 of the fuse layer 240. The lid 135 can include a second polarity region 220 having a first surface 222 and a second surface 224. The first surface 222 of the second polarity region 220 can couple with the second surface 236 of the isolation layer 232 such that the isolation layer 232 is disposed between the second surface 244 of the fuse layer 240 and the first surface 222 of the second polarity region 220. The lid 135 can include an outer gasket 260 coupled with the outer edge surface 207 of the first polarity region 205. The outer gasket 260 can couple with the first end 110 of the housing 105 to seal the battery cell 100.

While acts or operations may be depicted in the drawings or described in a particular order, such operations are not required to be performed in the particular order shown or described, or in sequential order, and all depicted or described operations are not required to be performed. Actions described herein can be performed in different orders.

Having now described some illustrative implementations, it is apparent that the foregoing is illustrative and not limiting, having been presented by way of example. Features that are described herein in the context of separate implementations can also be implemented in combination in a single embodiment or implementation. Features that are described in the context of a single implementation can also be implemented in multiple implementations separately or in various sub-combinations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular can include implementations including a plurality of these elements, and any references in plural to any implementation or element or act herein can include implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B′” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

The systems and methods described herein may be embodied in other specific forms without departing from the characteristics thereof. For example, the voltage across terminals of battery cells can be 5V or greater than (or less than) 5V. The foregoing implementations are illustrative rather than limiting of the described systems and methods. Scope of the systems and methods described herein is thus indicated by the appended claims, rather than the foregoing description, and changes that come within the meaning and range of equivalency of the claims are embraced therein.

Systems and methods described herein may be embodied in other specific forms without departing from the characteristics thereof. For example, descriptions of positive and negative electrical characteristics may be reversed. For example, elements described as negative elements can instead be configured as positive elements and elements described as positive elements can instead by configured as negative elements. Further relative parallel, perpendicular, vertical or other positioning or orientation descriptions include variations within +/−10% or +/−10 degrees of pure vertical, parallel or perpendicular positioning. References to “approximately,” “about” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. A battery cell of a battery pack to power an electric vehicle, the battery cell comprising:
a housing defining an inner region, the housing having a first end and a second end;
an electrolyte disposed within the inner region; and
a lid coupled with the first end of the housing, the lid comprising:
a first polarity region having an inner edge surface and an outer edge surface;
an inner gasket disposed within the inner edge surface of the first polarity region, the inner gasket having an inner isolation surface;
a fuse layer disposed within the inner isolation surface of the inner gasket, the fuse layer having a first surface and a second surface;
an isolation layer having a first surface and a second surface, the first surface of the isolation layer coupled with the second surface of the fuse layer;
a second polarity region having a first surface and a second surface, the first surface of the second polarity region coupled with the second surface of the isolation layer such that the isolation layer is disposed between the second surface of the fuse layer and the first surface of the second polarity region; and
an outer gasket coupled with the outer edge surface of the first polarity region, and the outer gasket coupled with the first end of the housing to seal the battery cell.

2. The battery cell of claim 1, comprising:
the first polarity region having a first surface and a second surface;
the first surface of the first polarity region forming a first polarity terminal for the battery cell; and
the second surface of the first polarity portion coupled with a first polarity portion of the electrolyte.

3. The battery cell of claim 1, comprising:
the first polarity region having an orifice; and
the inner gasket disposed within the orifice of the first polarity region such that an outer isolation surface of the inner gasket is coupled with the inner edge surface of the first polarity region.

4. The battery cell of claim 1, comprising:
the inner gasket comprising non-conductive material; and
the inner gasket electrically isolating the first polarity region from the second polarity region.

5. The battery cell of claim 1, comprising:
the inner gasket having an orifice; and
the fuse layer, the isolation layer, and the second polarity region are disposed within the orifice of the inner gasket.

6. The battery cell of claim 1, comprising:
the fuse layer having an outer ring portion and an inner ring portion; and
a tab portion coupling the inner ring portion with the outer ring portion.

7. The battery cell of claim 1, comprising:
the fuse layer having an outer ring portion and an inner ring portion;
the second polarity region having an outer portion and an inner portion; and
the inner ring portion of the fuse layer contacts the inner portion of the second polarity layer.

8. The battery cell of claim 1, comprising:
the fuse layer having an outer ring portion and an inner ring portion;
the second polarity region having an outer portion and an inner portion; and
the isolation layer disposed between the outer ring portion of the fuse layer and the outer portion of the second polarity layer.

9. The battery cell of claim 1, comprising:
the second polarity region having an outer portion and an inner portion; and
a scored region formed between the outer portion and inner portion; and
a tab region couples the outer portion and the inner portion.

10. The battery cell of claim 1, comprising:
the outer gasket having a crimped edge disposed over the outer edge surface of the first polarity region and portions of the first surface of the first polarity region.

11. The battery cell of claim 1, comprising:
the first surface of the second polarity region forming a second polarity terminal for the battery cell; and
the second surface of the second polarity region coupled with a second polarity portion of the electrolyte.

12. The battery cell of claim 1, comprising:
the inner gasket, the fuse layer, the isolation layer and the second polarity region coupled together to form a subassembly of the lid; and
the subassembly is disposed within the inner region of the first polarity region with the inner gasket electrically isolating the first polarity region from the second polarity region.

13. The battery cell of claim 1, comprising:
the battery cell disposed in a battery pack having multiple battery cell modules.

14. The battery cell of claim 1, comprising:
the battery cell disposed in a battery pack and the battery pack disposed in an electric vehicle.

15. A method of providing a battery cell for a battery pack to power an electric vehicle, the method comprising:
providing the battery pack having the battery cell, the battery cell having a housing that includes a first end and a second end and defines an inner region;
disposing an electrolyte within the inner region;
providing a first polarity region having an inner edge surface and an outer edge surface;
disposing an inner gasket within the inner edge surface of the first polarity region, the inner gasket having an inner isolation surface;
positioning a fuse layer within the inner isolation surface of the inner gasket, the fuse layer having a first surface and a second surface;
coupling a first surface of an isolation layer with the second surface of the fuse layer, the isolation layer having the first surface and a second surface;
providing a second polarity region having a first surface and a second surface, the first surface of the second polarity region coupled with the second surface of the isolation layer such that the isolation layer is disposed between the second surface of the fuse layer and the first surface of the second polarity region;
crimping an outer gasket with the outer edge surface of the first polarity region to form a lid for the battery cell; and
coupling the outer gasket with the first end of the housing to seal the battery cell.

16. The method of claim 15, comprising:
forming an orifice in the first polarity region; and
disposing the inner gasket within the orifice of the first polarity region such that an outer isolation surface of the inner gasket is coupled with the inner edge surface of the first polarity region.

17. The method of claim 15, comprising:
forming an orifice in the inner gasket; and
disposing the fuse layer, the isolation layer, and the second polarity region within the orifice of the inner gasket.

18. The method of claim 15, comprising:
forming a scored region between an outer portion of the second polarity region and an inner portion of the second polarity region; and
coupling the outer portion with the inner portion through a tab region.

19. The method of claim 15, comprising:
coupling the inner gasket, the fuse layer, the isolation layer and the second polarity region together to form a subassembly of the lid; and
disposing the subassembly within the inner region of the first polarity region with the inner gasket electrically isolating the first polarity region from the second polarity region.

20. An electric vehicle, comprising:
a battery pack having a battery cell to power the electric vehicle, the battery cell comprising:
a housing defining an inner region, the housing having a first end and a second end;
an electrolyte disposed within the inner region; and
a lid coupled with the first end of the housing, the lid comprising:
a first polarity region having an inner edge surface and an outer edge surface;
an inner gasket disposed within the inner edge surface of the first polarity region, the inner gasket having an inner isolation surface;
a fuse layer disposed within the inner isolation surface of the inner gasket, the fuse layer having a first surface and a second surface;
an isolation layer having a first surface and a second surface, the first surface of the isolation layer coupled with the second surface of the fuse layer;
a second polarity region having a first surface and a second surface, the first surface of the second polarity region coupled with the second surface of the isolation layer such that the isolation layer is disposed between the second surface of the fuse layer and the first surface of the second polarity region; and
an outer gasket coupled with the outer edge surface of the first polarity region, and the outer gasket coupled with the first end of the housing to seal the battery cell.
